(19) United States
(12) Patent Application Publication
(10) Pub. No.: US 2019/0326421 A1
(43) Pub. Date: Oct. 24, 2019

(54) METHOD FOR MANUFACTURING OXIDE SEMICONDUCTOR DEVICE

(71) Applicants: V TECHNOLOGY CO., LTD., Kanagawa (JP); TOHOKU UNIVERSITY, Miyagi (JP)

(72) Inventors: Tetsuya GOTO, Miyagi (JP); Michinobu MIZUMURA, Kanagawa (JP)

(21) Appl. No.: 16/461,765

(22) PCT Filed: Sep. 4, 2017
(86) PCT No.: PCT/JP2017/031820

§ 371 Date: May 16, 2019

(30) Foreign Application Priority Data
Dec. 12, 2016 (JP) 2016-240036

(51) Int. Cl. H01L 29/66; H01L 29/786; H01L 21/428; H01L 21/465

(52) U.S. Cl. CPC H01L 29/66969; H01L 21/465; H01L 21/428; H01L 29/7869

(57) ABSTRACT

In a manufacturing step of an oxide semiconductor device having an active layer of an oxide semiconductor, the step is simplified, thereby improving the productivity. A method for manufacturing an oxide semiconductor device having an active layer of an oxide semiconductor layer of indium (In), gallium (Ga), and zinc (Zn) includes a laser annealing treatment including irradiating an active layer formed region with a laser beam and imparting an etching resistance to the active layer.

### TECHNICAL FIELD

The present invention relates to a method for manufacturing an oxide semiconductor device.

### BACKGROUND ART

A TFT (Thin Film Transistor) is widely used for active elements of a flat panel display that is formed on a glass substrate. The TFT is a three-terminal device that consists of a gate, a source, and a drain as its basic constitution, uses a semiconductor thin film deposited on a substrate as an active layer in which electrons or holes flow, and has the function of applying voltage to the gate to control a current flowing to the active layer, and switch the current between the source and the drain.

As the active layer of the TFT, a polycrystal silicon thin film or an amorphous silicon thin film has been widely used. A spread of mobile electronic devices typified by a smart phone has provoked a demand for a small screen display to have image display performances with super high resolution/high image quality and low power consumption. As a TFT material capable of coping with this, an oxide semiconductor has attracted attention.

Out of oxide semiconductors, IGZO of an oxide of indium (In), gallium (Ga), and zinc (Zn) is known to be the TFT material capable of implementing higher resolution and lower power consumption of a display as compared with related-art amorphous silicon and the like. The following PTL 1 shows that a transparent amorphous oxide thin film is deposited by a vapor phase deposition method and consisted of elements of In, Ga, Zn, and O, a composition of the oxide is InGaO₃(ZnO)m (m is a natural number of less than 6) upon crystallization, the oxide is semi-insulating with an electron mobility of more than 1 cm²/(V sec) and an electron carrier density of 10¹⁶/cm³ or less without being doped with impurity ions, and the semi insulating transparent amorphous oxide thin film is used as an active layer of the TFT.

### CITATION LIST

### Patent Literature

### [PTL 1] Publication of Japanese Patent Application No. 2010-219538

### SUMMARY OF INVENTION

In the related art, manufacturing steps of a TFT using IGZO as an active layer have: a step (step S1) of forming a gate electrode layer on a base substrate (glass substrate) and performing patterning of the gate electrode; a step (step S2) of forming a gate insulation layer on the gate electrode; a step (step S3) of subjecting the gate insulation layer to a surface treatment; a step (step S4) of forming an active layer (IGZO layer) and patterning; a step (step S5) of forming an etch-stop layer and patterning; and a step (step S6) of forming an electrode layer (metal layer) and patterning the electrode layer (metal layer) into a source electrode and a drain electrode, and the like as shown in FIG. 1.

Thus, in the manufacturing of a TFT using IGZO as an active layer, patterning is required to be performed many times in the step S1, the step S4, the step S5, the step S6, and the like. Each time it requires a photolithography step involving mask exposure of a photoresist, and hence undesirably, the steps are complicated, and good productivity cannot be obtained.

Particularly, the etch-stop layer is a layer for preventing the active layer of IGZO from being cut during the subsequent electrode pattern formation and is not a functional layer. For this reason, there has been a demand for omitting the etch-stop layer and simplifying the layer formation.

The present invention was proposed in order to cope with such a problem. Namely, it is an object of the present invention to simplify the steps in the manufacturing steps of an oxide semiconductor device having an active layer of an oxide semiconductor and to improve the productivity.

In order to solve such a problem, the present invention has the following configuration.

A method for manufacturing an oxide semiconductor device having an active layer of an oxide semiconductor layer of indium (In), gallium (Ga), and zinc (Zn) is characterized by having a laser annealing step of irradiating the active layer formed region with a laser beam and imparting an etching resistance to the active layer.

### BRIEF DESCRIPTION OF DRAWINGS

FIG. 1 is an explanatory view for showing a part of a step of manufacturing a TFT using related-art IGZO as an active layer.

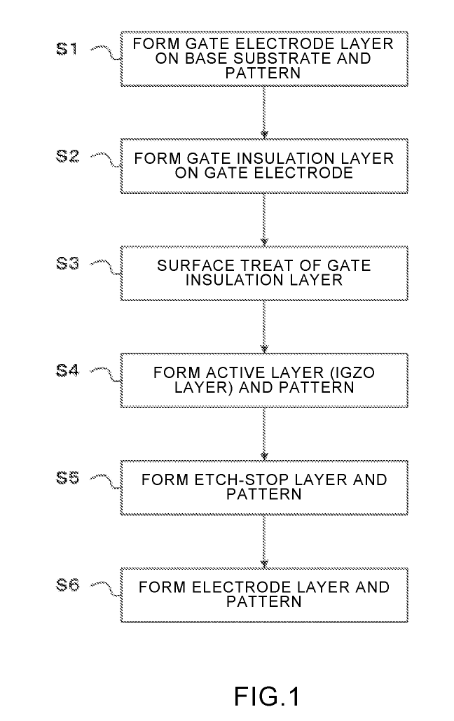

FIG. 2 is an explanatory view showing a method for manufacturing an oxide semiconductor device in accordance with an embodiment of the present invention.

FIG. 3 is an explanatory view showing a method for manufacturing an oxide semiconductor device in accordance with another embodiment of the present invention.

FIG. 4 is an explanatory view showing a method for manufacturing an oxide semiconductor device in accordance with a still other embodiment of the present invention.

### DESCRIPTION OF EMBODIMENTS

In a method for manufacturing an oxide semiconductor device in accordance with an embodiment of the present invention, a laser annealing treatment including irradiating an active layer formed region of an oxide semiconductor layer of indium (In), gallium (Ga), and zinc (Zn) with a laser beam is performed. As a result, an etching resistance is imparted to the active layer after the treatment. This finding has led to the completion of the invention. According to this, skipping a photolithography step to be performed for patterning of the active layer, the active layer subjected to the laser annealing treatment is directly subjected to an etching treatment, thereby removing the laser beam unirradiated regions. As a result, patterning of the active layer can be performed. Further, a metal layer can be directly formed on the patterned active layer to form an electrode pattern without forming an etch-stop layer.

According to such a method for manufacturing an oxide semiconductor device, by imparting the etching resistance to the active layer by the laser annealing treatment, it is possible to reduce the number of photolithography steps involving mask exposure of a photoresist. This enables manufacturing of an oxide semiconductor device with good productivity.

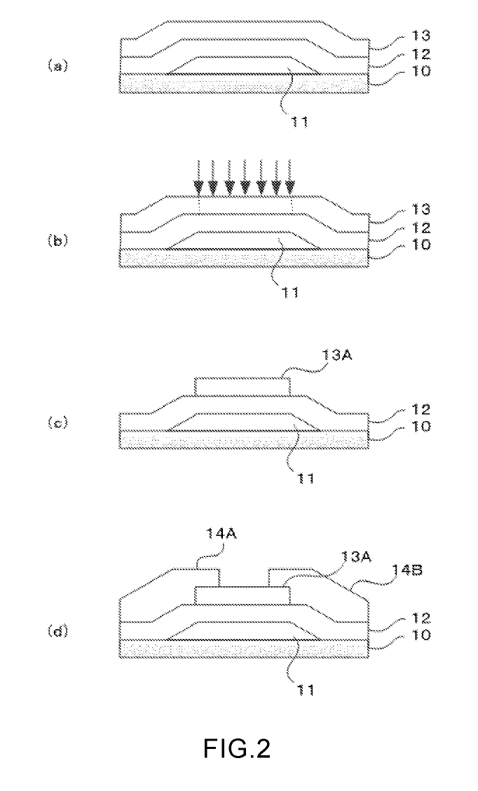

Below, specific manufacturing steps will be described by reference to the accompanying drawings. In FIG. 2, manufacturing is performed in the order of steps (a), (b), (c), and (d). In the step (a), on a base substrate (glass substrate) 10, a gate electrode 11, a gate insulation layer 12, and an oxide semiconductor layer (IGZO layer) 13 are formed. For the gate electrode 11, for example, a Mo, Ti, or TiN layer is formed (e.g., film thickness 100 nm) by sputtering or the like, and the electrode pattern is formed by the photolithography step and an etching step. For the gate insulation layer 12, on the gate electrode 11, for example, a SiO₂ layer is formed (e.g., film thickness 100 nm) by plasma CVD or the like. For the oxide semiconductor layer 13, on the gate insulation layer 12, the IGZO layer is formed by magnetron sputtering or the like.

In the step (b), the laser annealing treatment including irradiating the active layer formed region of the formed oxide semiconductor layer 13 with a laser beam is performed. The laser beam to be applied is, for example, an excimer laser (XeF wavelength 351 nm or KrF wavelength 248 nm, energy density 150 mJ/cm², 50 shots). Prior to the laser annealing treatment, channel doping (Si ion implantation) may be performed, if required.

In the step (c), the oxide semiconductor layer 13 subjected to the laser annealing treatment is subjected to the etching treatment, thereby patterning the active layer 13A. Herein, the laser annealing treatment imparts the etching resistance to the active layer formed region. For this reason, the photolithography step of subjecting the photoresist to mask exposure is omitted, and the oxide semiconductor layer 13 is directly immersed in an etchant. As a result, the laser beam unirradiated portion of the oxide semiconductor layer 13 is removed by etching, thereby forming the active layer 13A.

The etching resistance of the IGZO layer by the laser annealing treatment will be described. It has been found that the IGZO layer is crystalized only at the laser-irradiated region depending upon conditions. It has been observed as follows: with both a XeF laser and a KrF laser, the film density increased for densification although the layer is amorphous in the region with an energy density of between 20 mJ/cm² and 140 mJ/cm², and crystallization was caused in the region with an energy density of 140 mJ/cm² to 200 mJ/cm². It has been found that such crystallization and densification are caused with more efficiency by locally irradiating the region with an area of about 100 μm×100 μm or less with a laser beam and suppressing expansion of the whole film. Then, it has been found that the crystalized IGZO film has an improved wet etching resistance. For example, it has been found that the crystalized IGZO (film thickness 50 nm) is not etched even when immersed in phosphoric acid and a mixed solution of phosphoric acid/nitric acid/acetic acid for two minutes or more. On the other hand, in the amorphous IGZO region, the 50-nm film thickness was etched in about 1 minute with phosphoric acid and in about 20 seconds with a mixed solution of phosphoric acid/nitric acid/acetic acid.

In the step (d), on the active layer 13A imparted with the etching resistance by the laser annealing treatment, without forming the etch-stop layer, the electrode pattern is directly formed. Namely, on the active layer 13A and the gate insulation layer 12, an Al layer is formed, and by the photolithography step and the etching step, a source electrode 14A is formed. Further, on the active layer 13A and the gate insulation layer 12, an Al layer is formed, and by the photolithography step and the etching step, a drain electrode 14B is formed. Subsequently, appropriate steps such as formation of a passivation film (e.g., SiO₂) are performed.

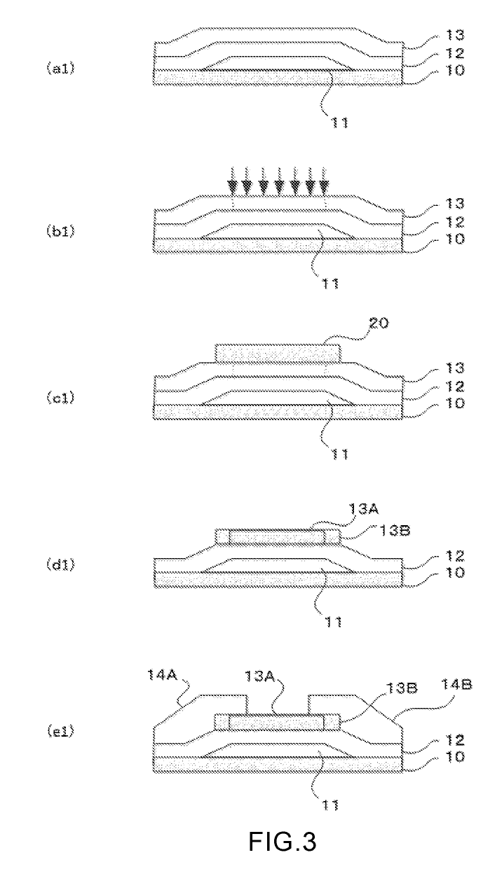

In another embodiment shown in FIG. 3, manufacturing is performed in the order of steps (a1), (b1), (c1), (d1), and (e1). The steps (a1) and (b1) are the same as the steps (a) and (b) shown in FIG. 2. In this embodiment, in the step (c1), on the active layer formed region imparted with an etching resistance by a laser annealing treatment, a pattern of a photoresist 20 is formed by a photolithography step; in the step (d1), an etching treatment is performed so that the pattern of the photoresist 20 is left, and an oxide semiconductor layer 13 is removed by etching, followed by removal of the photoresist 20; as a result, a pattern 13B including the active layer 13A is formed. In the subsequent step (e1), as in the step (d) in FIG. 2, patterns of a source electrode 14A and a drain electrode 14B are formed. The IGZO layer imparted with an etching resistance also has an improved resistance to dry etching. For this reason, for patterning, not only a wet process but also a dry etching process may be used.

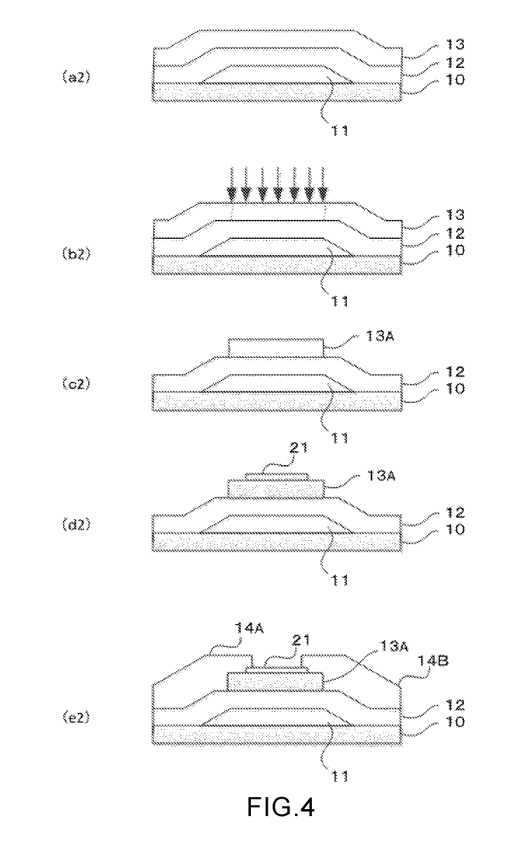

In a still other embodiment shown in FIG. 4, manufacturing is performed in the order of steps (a2), (b2), (c2), (d2), and (e2). The steps (a2) to (c2) are the same as the steps (a) to (c) shown in FIG. 2. In this embodiment, after patterning the active layer 13A, in the step (d2), on the active layer 13A, a pattern of an etch-stop layer 21 is formed. Subsequently, in the step (e2), patterns of a source electrode 14A and a drain electrode 14B are formed. Herein, for pattern formation of the etch-stop layer 21 and pattern formation of the source electrode 14A and the drain electrode 14B, a photolithography step of subjecting a photoresist to mask exposure, and an etching step are performed.

In the embodiment described above, the laser annealing treatment imparts the etching resistance to the active layer 13A. As a result, the photolithography step of subjecting the photoresist to mask exposure can be omitted in one or both of patterning of the active layer 13A and formation of the electrode patterns. This can simplify the steps.

### REFERENCE SIGNS LIST

10 Base substrate (Glass substrate)
11 Gate electrode
12 Gate insulation layer
13 Oxide semiconductor layer
13A Active layer
14A Source electrode
14B Drain electrode
20 Photoresist
21 Etch-stop layer

1. A method for manufacturing an oxide semiconductor device having an active layer of an oxide semiconductor layer of indium (In), gallium (Ga), and zinc (Zn),
the method comprising a laser annealing treatment including irradiating the active layer formed region with a laser beam and imparting an etching resistance to the active layer.

2. The method for manufacturing an oxide semiconductor device according to claim 1,
wherein the laser annealing treatment is performed after forming the oxide semiconductor layer, and
a photolithography step is omitted, and a laser beam-unirradiated portion of the oxide semiconductor layer is removed by etching.

3. The method for manufacturing an oxide semiconductor device according to claim 1,
wherein a metal layer is directly formed on the patterned active layer to form an electrode pattern.

4. The method for manufacturing an oxide semiconductor device according to claim 2,
wherein a metal layer is directly formed on the patterned active layer to form an electrode pattern.

5. An oxide semiconductor device having an active layer of an oxide semiconductor layer composed of indium (In), gallium (Ga), and zinc (Zn),
wherein the active layer formed region is imparted an etching resistance by a laser annealing treatment.
